(19) United States
(12) Patent Application Publication
(10) Pub. No.: US 2015/0380428 A1
(43) Pub. Date: Dec. 31, 2015

(54) SEMICONDUCTOR MEMORY DEVICE AND METHOD FOR MANUFACTURING SAME

(71) Applicant: Kabushiki Kaisha Toshiba, Minato-ku (JP)

(72) Inventor: Toru MATSUDA, Yokkaichi (JP)

(73) Assignee: Kabushiki Kaisha Toshiba, Minato-ku (JP)

(21) Appl. No.: 14/484,650

(22) Filed: Sep. 12, 2014

Related U.S. Application Data
(60) Provisional application No. 62/018,163, filed on Jun. 27, 2014.

(51) Int. Cl. H01L 27/115; H01L 29/49; H01L 29/423; H01L 29/45

(52) U.S. Cl. CPC H01L 27/11582; H01L 27/11565; H01L 29/456; H01L 29/4916; H01L 29/4234

(57) ABSTRACT

According to one embodiment, a semiconductor memory device includes a source layer; a stacked body; a columnar section; and a contact section extending in the stacking direction and piercing through the stacked body and connected to the source layer. The columnar section including: a channel body extending in the stacking direction and including a lower end, the lower end projecting into the source layer; and a charge storage film provided between the channel body and each of the electrode layers. The source layer including: a first film including metal; and a second film having electric conductivity provided between the first film and the lower end of the channel body, the second film being in contact with the lower end and covering the lower end.

### CROSS-REFERENCE TO RELATED APPLICATIONS

This application is based upon and claims the benefit of priority from the prior U.S. Provisional Patent Application 62/018,163 field on Jun. 27, 2014; the entire contents of which are incorporated herein by reference.

### FIELD

Embodiments described herein relate generally to a semiconductor memory device and method for manufacturing same.

### BACKGROUND

A memory device having a three-dimensional structure is proposed in which a memory hole is formed in a stacked body formed by stacking, via insulating layers, a plurality of electrode layers functioning as control gates in memory cells and a silicon body functioning as a channel is provided on the sidewall of the memory hole via a charge storage film.

The memory hole is formed by, for example, an RIE (Reactive Ion Etching) method in the stacked body including the plurality of electrode layers and the plurality of insulating layers in the three-dimensional memory device. A memory film including the charge storage film is formed on the inner wall of the memory hole and a channel body is formed on the inner side of the memory film. It is proposed to etch and remove, in a structure in which, for example, a source layer is provided under the stacked body, the memory film formed at the bottom of the memory hole in order to connect the lower end of the channel body to the source layer. In this case, the memory film formed on the sidewall of the memory hole is also sometimes affected by the etching.

### BRIEF DESCRIPTION OF THE DRAWINGS

FIG. 1 is a schematic perspective view of a memory cell array in an embodiment;

FIG. 2A is a schematic top view of a memory strings in the embodiment and FIG. 2B is a schematic sectional view of the memory strings in the embodiment;

FIG. 3 is an enlarged schematic sectional view of a part of the columnar section of the embodiment;

FIG. 4A to FIG. 14B are schematic views showing a method for manufacturing the semiconductor memory device of the embodiment;

FIG. 15A is a schematic top view of the memory strings in another embodiment;

FIG. 15B is a schematic sectional view of the memory strings in the other embodiment; and

FIG. 16A to FIG. 26B are schematic views showing a method for manufacturing the semiconductor memory device of the other embodiment.

### DETAILED DESCRIPTION

According to one embodiment, a semiconductor memory device includes a source layer; a stacked body provided on the source layer and including a plurality of electrode layers and a plurality of insulating layers respectively provided among the electrode layers; a columnar section extending in a stacking direction of the stacked body and piercing through the stacked body; and a contact section extending in the stacking direction and piercing through the stacked body and connected to the source layer. The columnar section including: a channel body extending in the stacking direction and including a lower end, the lower end projecting into the source layer; and a charge storage film provided between the channel body and each of the electrode layers. The source layer including: a first film including metal; and a second film having electric conductivity provided between the first film and the lower end of the channel body, the second film being in contact with the lower end and covering the lower end.

Embodiments are described below with reference to the drawings. Note that in the drawings, the same components are denoted by the same reference numerals and signs.

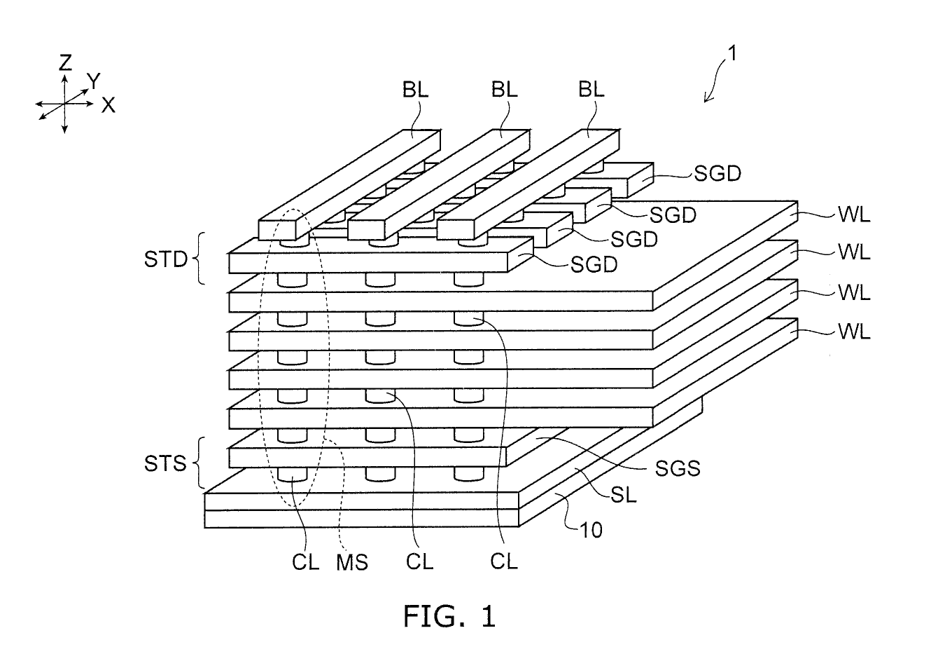

FIG. 1 is a schematic perspective view of a memory cell array 1 in an embodiment. In FIG. 1, to clearly show the figure, insulating layers and the like are not shown.

In FIG. 1, two directions parallel to a major surface of a substrate 10 and orthogonal to each other are represented as X-direction and Y-direction. A direction orthogonal to both of the X-direction and the Y-direction is represented as Z-direction (stacking direction).

The memory cell array 1 includes a plurality of memory strings MS.

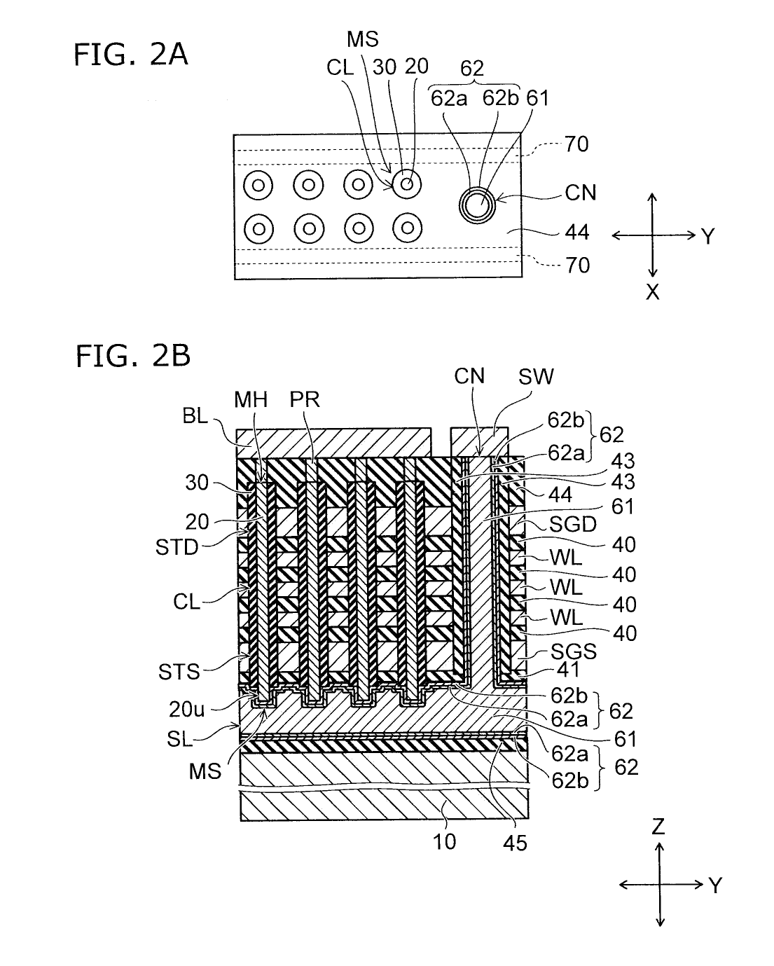

FIG. 2A is a schematic top view of the memory strings MS. FIG. 2A represents an upper surface parallel to an XY plane in FIG. 1.

FIG. 2B is a schematic sectional view of the memory strings MS. FIG. 2B represents a cross section parallel to a YZ plane in FIG. 1.

A source layer SL (a source line) is provided on the substrate 10 via an insulating layer 45. A source side selection gate SGS (a lower selection gate or a lower gate layer) is provided on the source layer SL via an insulating layer 41.

An insulating layer 40 is provided on the source side selection gate SGS. A stacked body formed by alternately stacking a plurality of electrode layers WL and a plurality of insulating layers 40 one by one is provided on the insulating layer 40. The stacked body includes the source side selection gate SGS, a drain side selection gate SGD, and a plurality of electrode layers WL. The number of the electrode layers WL shown in the figure is an example and may be any number.

The source side selection gate SGS, the drain side selection gate SGD, and the electrode layers WL are silicon layers including silicon as a main component. For example, boron is doped in the silicon layers as impurities for imparting electric conductivity. The source side selection gate SGS, the drain side selection gate SGD, and the electrode layers WL may include metal silicide. The insulating layers 40 mainly include, for example, silicon oxide.

The source side selection gate SGS is provided between the source layer SL and the electrode layer WL at the bottom.

The insulating layer 40 is provided on the electrode layer WL at the top. The drain side selection gate SGD (an upper selection gate or an upper gate layer) is provided on the insulating layer 40. The drain side selection gate SGD and the source side selection gate SGS are thicker than one electrode layer WL.

Columnar sections CL extending in the Z-direction are provided in the stacked body. The columnar sections CL pierce through the drain side selection gate SGD, the plurality of electrode layers WL under the drain side selection gate SGD, and the source side selection gate SGS. The columnar sections CL are formed in a circular or elliptical columnar shape.

A contact section CN extending in the Z-direction is provided in the stacked body. The contact section CN pierces through the drain side selection gate SGD, the plurality of electrode layers WL under the drain side selection gate SGD, and the source side selection gate SGS and reaches the source layer SL. The contact section CN is formed in, for example, a circular or elliptical columnar shape. The contact section CN is integrally provided with the source layer SL and electrically connected to the source layer SL.

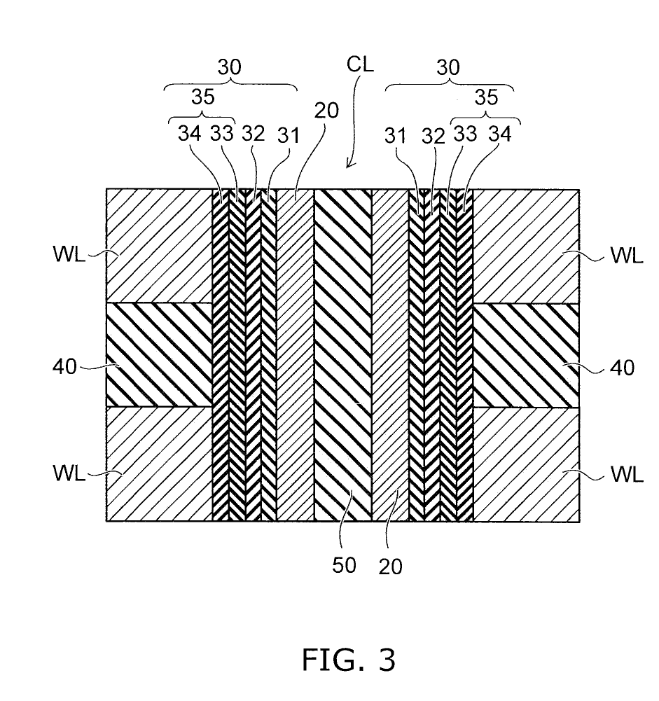

FIG. 3 is an enlarged schematic sectional view of a part of the columnar section CL of the embodiment.

The columnar section CL is formed in an I-shaped memory hole MH (FIG. 7) formed in the stacked body including the plurality of electrode layers WL and the plurality of insulating layers 40. In the memory hole MH, a channel body 20 functioning as a semiconductor channel is provided. The channel body 20 is, for example, a silicon film including silicon as a main component. The impurity concentration of the channel body 20 is lower than, for example, the impurity concentration of the electrode layers WL.

The channel body 20 is provided to extend in the stacking direction. The upper end of the channel body 20 is connected to a bit line BL (e.g., a metal film) shown in FIG. 1. The lower end of the channel body 20 is connected to the source layer SL. The bit line BL extends in the Y-direction.

A memory film 30 is provided between the inner wall of the memory hole MH and the channel body 20. The memory film 30 includes a block insulating film 35, a charge storage film 32, and a tunnel insulating film 31. The memory film 30 is provided to extend in the stacking direction.

The block insulating film 35, the charge storage film 32, and the tunnel insulating film 31 are provided in order from the electrode layers WL side between the electrode layers WL and the channel body 20. The block insulating film 35 is in contact with the electrode layers WL. The tunnel insulating film 31 is in contact with the channel body 20. The charge storage film 32 is provided between the block insulating film 35 and the tunnel insulating film 31.

The channel body 20 is provided in a cylindrical shape extending in the stacking direction of the stacked body. The memory film 30 is provided in a columnar shape while extending in the stacking direction of the stacked body to surround the outer circumferential surface of the channel body 20. The electrode layers WL surround the channel body 20 via the memory film 30. A core insulating film 50 is provided on the inner side of the channel body 20. The core insulating film 50 is, for example, a silicon oxide film.

The channel body 20 functions as channels in memory cells. The electrode layers WL function as control gates of the memory cells. The charge storage film 32 functions as a data memory layer that stores electric charges injected from the channel body 20. That is, the memory cells having a structure in which the control gates surround the channels are formed in crossing portions of the channel body 20 and the electrode layers WL.

A semiconductor memory device of the embodiment can electrically freely perform erasing and writing of data and can retain stored contents even if a power supply is turned off.

The memory cells are, for example, memory cells of a charge trap type. The charge storage film 32 includes a large number of trap sites that capture electric charges. The charge storage film 32 is, for example, a silicon nitride film.

When electric charges are injected to the charge storage film 32 from the channel body 20 or when electric charges stored in the charge storage film 32 diffuse to the channel body 20, the tunnel insulating film 31 functions as a potential barrier. The tunnel insulating film 31 is, for example, a silicon oxide film.

A stacked film (an ONO film) having a structure in which a silicon nitride film is sandwiched by a pair of silicon oxide films may be used as the tunnel insulating film 31. When the ONO film is used as the tunnel insulating film 31, an erasing operation can be performed with a low electric field compared with a single layer of the silicon oxide film.

The block insulating film 35 prevents the chargers stored in the charge storage film 32 from diffusing to the electrode layers WL. The block insulating film 35 includes a cap film 34 provided in contact with the electrode layers WL and a block film 33 provided between the cap film 34 and the charge storage film 32.

The block film 33 is, for example, a silicon oxide film. The cap film 34 is a film having a dielectric constant higher than the dielectric constant of silicon oxide and is, for example, a silicon nitride film. By providing the cap film 34 in contact with the electrode layers WL, it is possible to suppress back tunnel electrons injected from the electrode layers WL during erasing. That is, by using a stacked film of the silicon oxide film and the silicon nitride film as the block insulating film 35, it is possible to improve charge blocking properties.

As shown in FIGS. 1 and 2B, a drain side selection transistor STD is provided at the upper end of the columnar section CL in the I-shaped memory string MS and a source side selection transistor STS is provided at the lower end of the columnar section CL.

The memory cells, the drain side selection transistor STD, and the source side selection transistor STS are vertical transistors in which an electric current flows in the stacking direction (the Z-direction) of the stacked body.

The drain side selection gate SGD functions as a gate electrode (a control gate) of the drain side selection transistor STD. An insulating film functioning as a gate insulating film of the drain side selection transistor STD is provided between the drain side selection gate SGD and the channel body 20.

The source side selection gate SGS functions as a gate electrode (a control gate) of the source side selection transistor STS. An insulating film functioning as a gate insulating film of the source side selection transistor STS is provided between the source side selection gate SGS and the channel body 20.

A plurality of memory cells including the electrode layers WL as control gates are provided between the drain side selection transistor STD and the source side selection transistor STS.

The plurality of memory cells, the drain side selection transistor STD, and the source side selection transistor STS are connected in series through the channel body 20 and configure one I-shaped memory string MS. The plurality of memory strings MS are arrayed in the X-direction and the Y-direction, whereby the plurality of memory cells are three-dimensionally provided in the X-direction, the Y-direction, and the Z-direction.

According to the embodiment, as shown in FIG. 2B, the source layer SL includes a source film 61 (a first film) and a barrier film 62 (a second film). The source film 61 includes metal and is, for example, a tungsten film including tungsten as a main component. The barrier film 62 has electric conductivity and includes, for example, metal.

The source film 61 is provided between a foundation layer (the insulating layer 45) and the bottom layer (the insulating layer 41) of the stacked body to occupy a most region of the source layer SL.

A lower end 20u of the channel body 20 projects to the source layer SL. The lower end 20u of the channel body 20 includes an end face (a bottom surface) and a side surface not covered with the memory film 30.

The end face and the bottom surface of the lower end 20u of the channel body 20 are in contact with the barrier film 62. The lower end 20u of the channel body 20 is covered with the barrier film 62 and covered with the source film 61 via the barrier film 62. That is, the channel body 20 is electrically connected to the source layer SL via the lower end 20u.

According to the embodiment, the channel body 20 is in contact with the source layer SL not only on the end face (the bottom surface) of the lower end 20u but also on the side surface. Therefore, the area of the channel body 20 in contact with the source layer SL increases and contact resistance decreases.

The barrier film 62 includes, for example, a conductive film 62a and a conductive film 62b. The conductive film 62a includes, for example, metal and is, for example, a titanium nitride film. The conductive film 62b is, for example, a silicon film doped with impurities.

The conductive film 62b covers, in a conformal manner, the end face and the side surface of the lower end 20u of the channel body 20 projecting to the source layer SL and is in contact with the end face and the side surface of the lower end 20u. By appropriately controlling the impurity concentration of the conductive film 62b, which is the silicon film, it is possible to reduce the contact resistance of a contact section of the channel body 20 and the source layer SL.

The conductive film 62a is provided to cover the conductive film 62b. The conductive film 62a is provided between the conductive film 62b and the source film 61 and improves adhesion between the conductive film 62b and the source film 61. That is, the conductive film 62a functions as an adhesive film between the semiconductor film and the metal film. The barrier film 62 may be a single layer.

The contact section CN includes a source film 61 (a third film) and a barrier film 62 (a fourth film). That is, in the contact section CN, materials (the source film 61 and the barrier film 62) same as the materials of the source layer SL are used.

The third film (the source film 61) of the contact section CN extends in the stacking direction of the stacked body piercing through the stacked body and is integrally connected to the source layer SL. The fourth film (the barrier film 62) of the contact section CN is provided between the third film (the source film 61) and the stacked body and forms the sidewall of the contact section CN.

An insulating film 43 is provided between the sidewall (the barrier film 62) of the contact section CN and the electrode layers WL of the stacked body. The electrode layers WL and the contact section CN are not short-circuited. The insulating film 43 is provided between the source side selection gate SGS and the contact section CN and between the drain side selection gate SGD and the contact section CN.

The source film 61 and the barrier film 62 are integrally provided in a region where the source layer SL and the contact section CN are formed. In a region where the columnar contact section CN is formed, the conductive film 62b, the conductive film 62a, and the source film 61 are provided in order from the outer side.

As shown in FIG. 2B, an insulating layer 44 is provided on the drain side selection gate SGD. The bit line BL is provided on the insulating layer 44. The bit line BL is connected to the upper end of the channel body 20 via a plug PR that pierces through the insulating layer 44.

The upper end of the contact section CN of the source layer SL is connected to a source wire SW. Therefore, the source layer SL is electrically connected to an upper layer wire (the source wire SW), which is provided on the stacked body, via the contact section CN.

The source layer SL is separated into a plurality of regions (blocks) by separating sections 70 shown in FIG. 2A. The separating sections 70 are insulating films including, for example, silicon nitride or silicon oxide. The separating sections 70 extend in, for example, the Y-direction. The source layer SL is divided in the X-direction by the separating sections 70.

The stacked body is formed on the separating sections 70. As described below, a sacrificial layer is once embedded in a region where the source layer SL is formed. After the stacked body is formed on the sacrificial layer, the sacrificial layer is removed. In this case, the separating sections 70 support the stacked body.

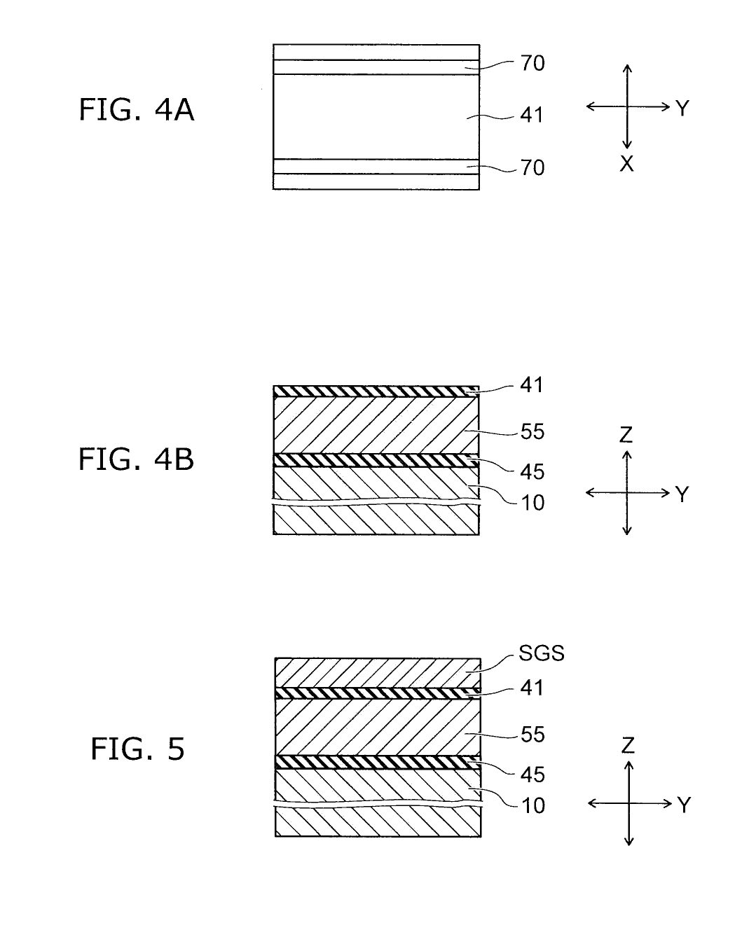

A method for manufacturing the semiconductor memory device of the embodiment is described with reference to FIGS. 4A to 14B.

FIGS. 4B, 5 to 10, 11B, 12B, 13B, and 14B are schematic sectional views.

FIGS. 4A, 11A, 12A, 13A, and 14A are respectively schematic top views of processes shown in FIGS. 4B, 11B, 12B, 13B, and 14B.

As shown in FIG. 4B, the insulating layer 45 functioning as the foundation layer of the source layer SL is formed on the substrate 10. A sacrificial layer 55 is formed on the insulating layer 45. In a process described below, the sacrificial layer 55 is removed and the source layer SL is formed in a portion where the sacrificial layer 55 is removed (a replace process). As the sacrificial layer 55, for example, amorphous silicon is used. The insulating layer 41 is formed on the sacrificial layer 55.

A transistor of a not-shown peripheral circuit section is formed between the substrate 10 and the insulating layer 45. The transistor controls the memory cells.

After the insulating layer 41 is formed, a groove that pierces through the insulating layer 41 and the sacrificial layer 55 is formed. An insulating film is embedded in the groove. Consequently, as shown in FIG. 4A, the separating sections 70 (a dividing section for a source layer) is formed. The separating sections 70 are formed to extend in the Y-direction and to be separated in the X-direction. The sacrificial layer 55 is divided into a plurality of regions by the separating sections 70.

As shown in FIG. 5, the source side selection gate SGS (the lower gate layer) is formed on the insulating layer 41.

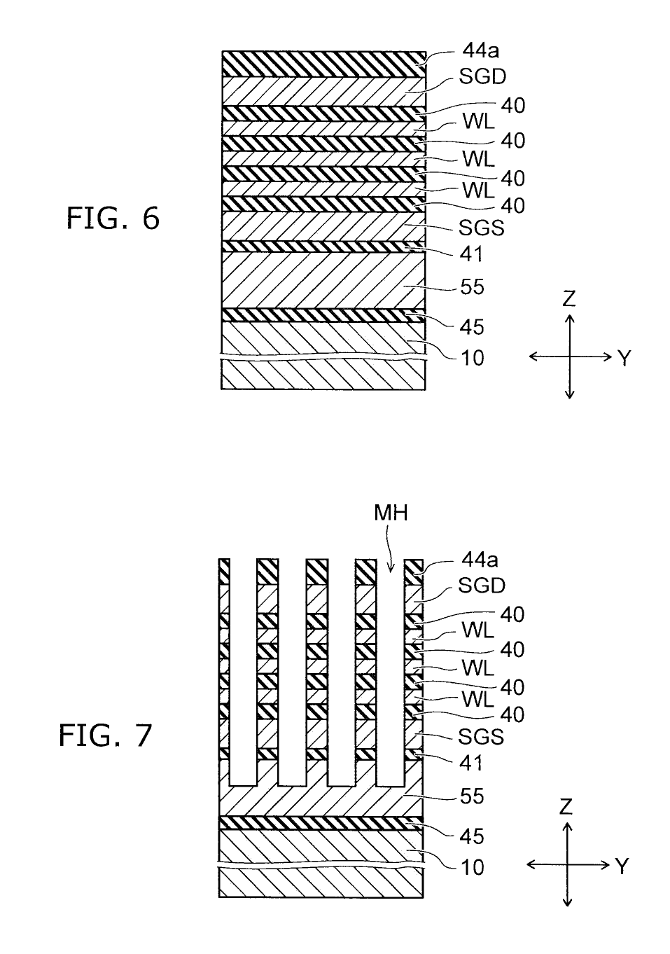

Thereafter, on the insulating layer 41, as shown in FIG. 6, a stacked body in which the insulating layers 40 (interlayer films) and the electrode layers WL are alternately stacked is formed. The drain side selection gate SGD (the upper gate layer) is formed on the electrode layer WL at the top via the insulating layer 40. An insulating layer 44a is formed on the drain side selection gate SGD.

As shown in FIG. 7, a plurality of memory holes MH are formed in the stacked body. The memory holes MH are formed by, for example, an RIE method using a not-shown mask. The memory holes MH pierce through the insulating layer 44a to the insulating layer 41 and reach the sacrificial layer 55.

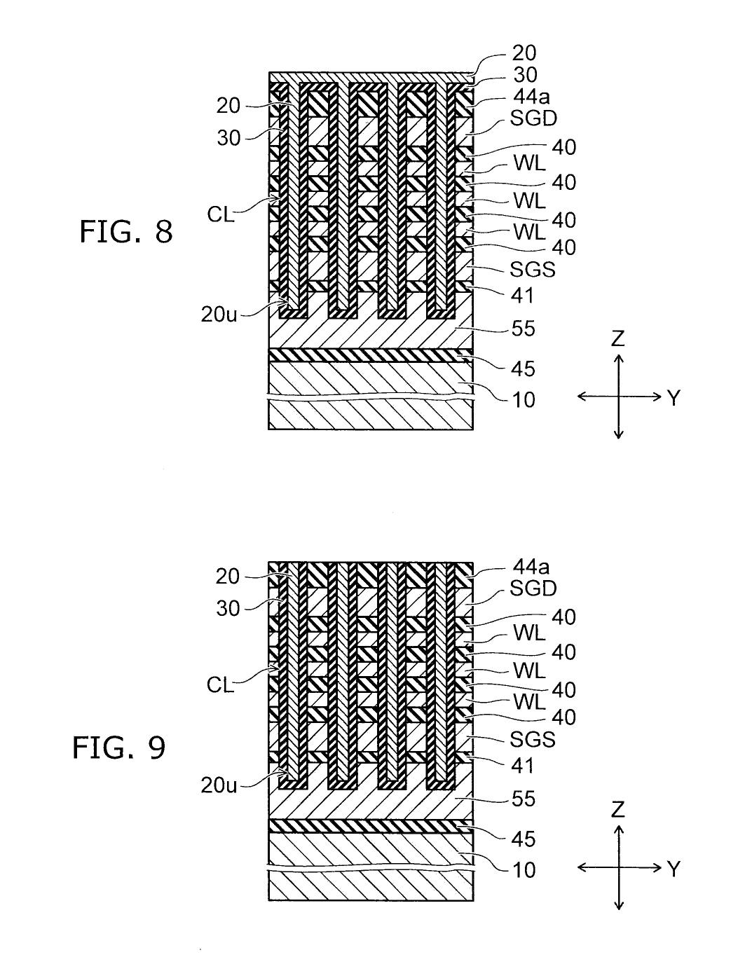

After the memory holes MH are formed, as shown in FIG. 8, the films (the films including the memory film 30 and the channel bodies 20) shown in FIG. 3 are formed in order on the inner walls (the sidewalls and the bottoms) of the memory holes MH. Consequently, the columnar sections CL are formed.

In this case, the lower ends 20u of the channel bodies 20 project to the sacrificial layer 55 and are covered with the memory film 30. The memory film 30 that covers the lower ends 20u of the channel bodies 20 is covered with the sacrificial layer 55.

The films formed on the insulating layer 44a are removed as shown in FIG. 9. Thereafter, the insulating layer 44 is formed on the columnar sections CL and the stacked body.

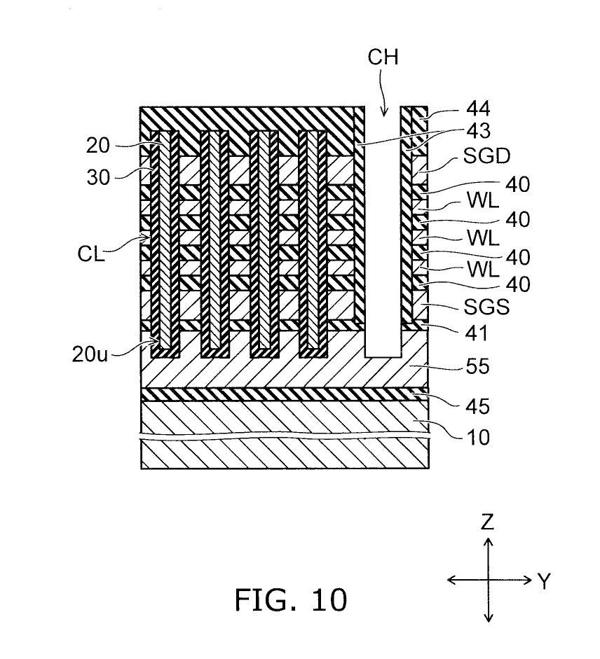

As shown in FIG. 10, a contact hole CH (a pierce-through section) that pierces through the insulating layer 44 to the insulating layer 41 and reaches the sacrificial layer 55 is formed in the stacked body. The sacrificial layer 55 is exposed in the bottom of the contact hole CH. The contact hole CH (the pierce-through section) is not limited to the hole and may be a groove (a slit).

The insulating film 43 is formed on the sidewall of the contact hole CH. Therefore, the side surfaces of the electrode layers WL, the source side selection gate SGS, and the drain side selection gate SGD exposed on the sidewall of the contact hole CH are covered with the insulating film 43.

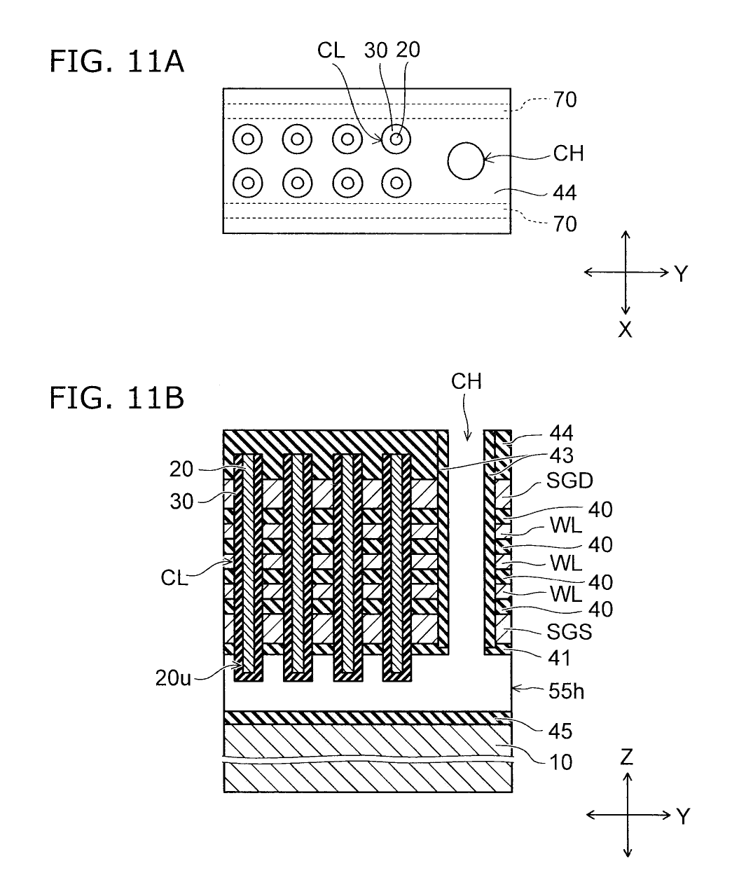

As shown in FIG. 11B, the sacrificial layer 55 is removed with etching performed through the contact hole CH. As a method for removing the sacrificial layer 55, for example, alkali chemical liquid is used. Consequently, a cavity 55h is formed under the stacked body. The cavity 55h is connected to the contact hole CH. The lower ends 20u of the channel bodies 20 project to the cavity 55h and are covered with the memory film 30. The memory film 30 that covers the lower ends 20u of the channel bodies 20 is exposed in the cavity 55h.

In this case, the stacked body is supported by the separating sections 70 shown in FIG. 11A formed to partition the cavity 55h in the X-direction.

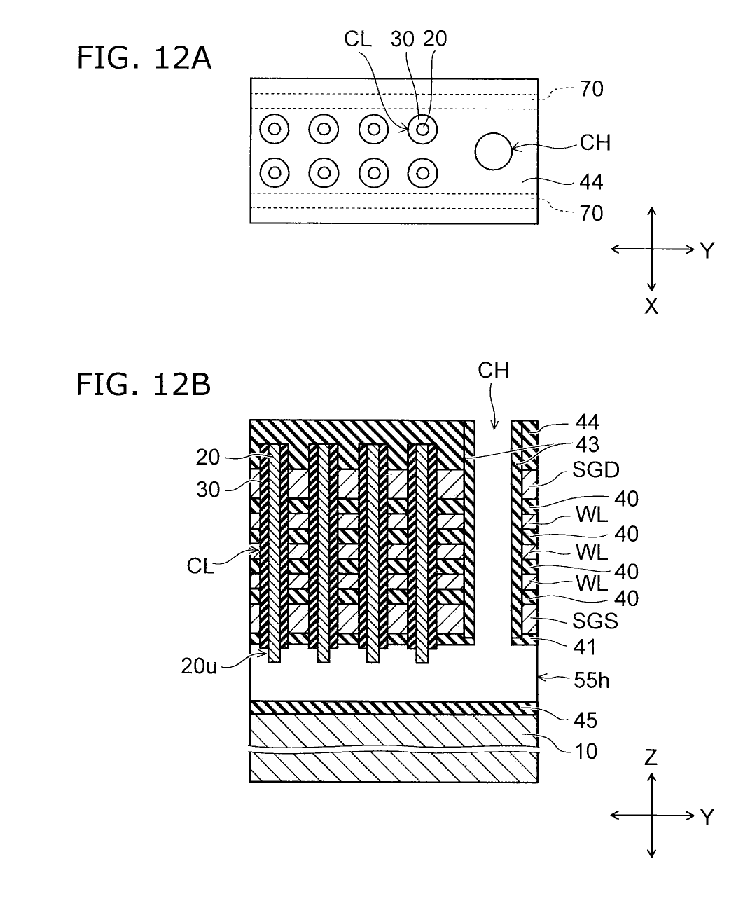

Thereafter, the memory film 30 exposed in the cavity 55h is removed with etching performed through the contact hole CH. For example, the memory film 30 is removed by etching using CDE (Chemical Dry Etching). Consequently, as shown in FIG. 12B, the lower ends 20u of the channel bodies 20 projecting to the cavity 55h are exposed in the cavity 55h without being covered with the memory film 30.

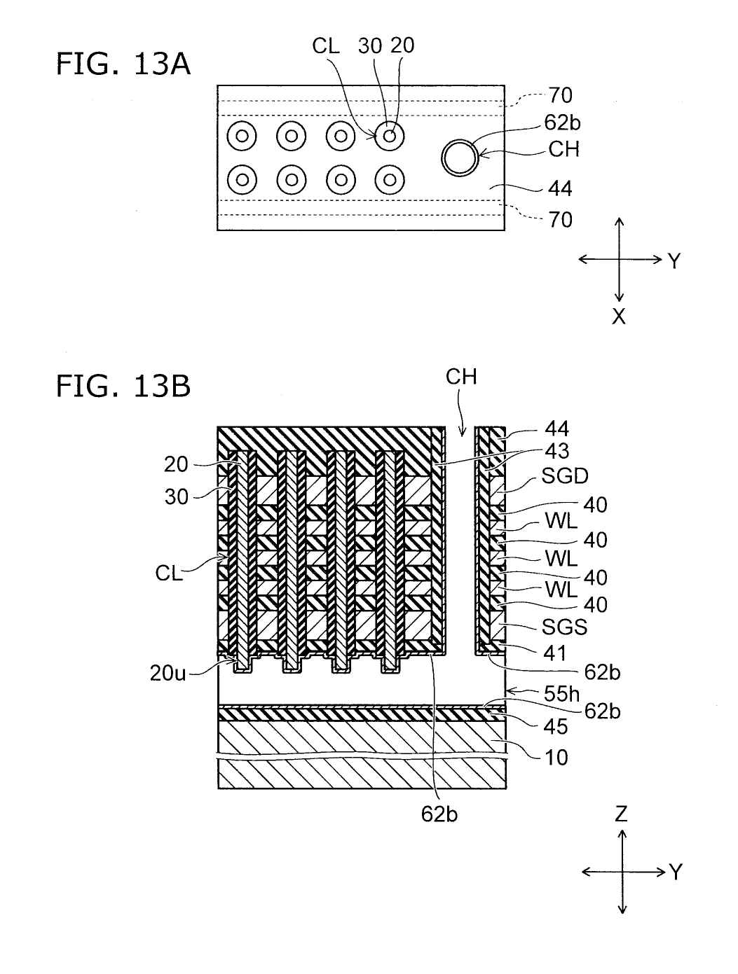

Thereafter, as shown in FIG. 13B, the conductive film 62b is formed on the inner wall of the cavity 55h and the sidewall of the contact hole CH. The conductive film 62b is integrally formed with the inner wall of the cavity 55h and the sidewall of the contact hole CH. That is, the same conductive film 62b is formed on the sidewall of the contact hole CH and the inner wall of the cavity 55h.

The lower ends 20u of the channel bodies 20 projecting to the cavity 55h are covered with the conductive film 62b. The conductive film 62b is formed in a conformal manner along the end faces (the bottom surfaces) and the side surfaces of the lower ends 20u.

The conductive film 62b is, for example, a silicon film doped with impurities.

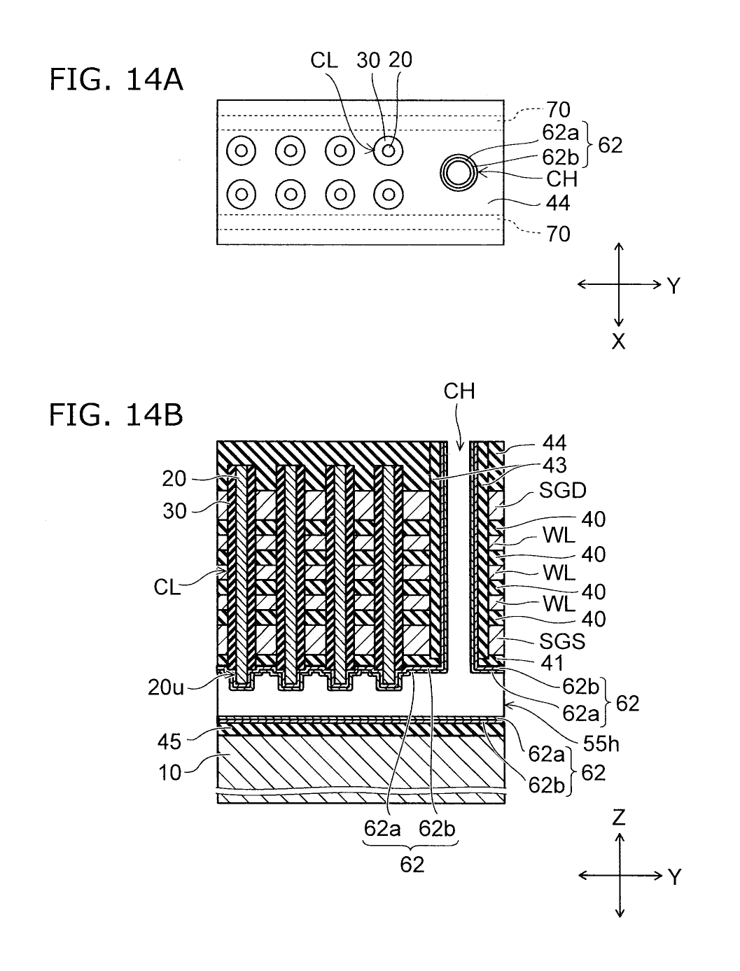

As shown in FIG. 14B, another conductive film 62a is formed on the conductive film 62b. The conductive film 62a covers the inner wall of the cavity 55h and the sidewall of the contact hole CH via the conductive film 62b. The conductive film 62a covers the lower ends 20u of the channel bodies 20 in a conformal manner via the conductive film 62b. Thereafter, the source film 61 is embedded in the cavity 55h and the contact hole CH. Consequently, the source layer SL is formed as shown in FIG. 2B.

Thereafter, the bit lines BL, the source wire SW, and the like are formed on the insulating layer 44. Consequently, the semiconductor memory device of the embodiment is obtained.

According to the embodiment, by forming the source layer SL with the replace process using the sacrificial layer 55, it is possible to etch only the memory film 30 formed in the bottom surface sections of the memory holes MH. Therefore, the memory film 30 of the memory cells formed above the lower ends 20u of the channel bodies 20 is not affected by the etching. Therefore, it is possible to suppress characteristic fluctuation and deterioration of the memory cells.

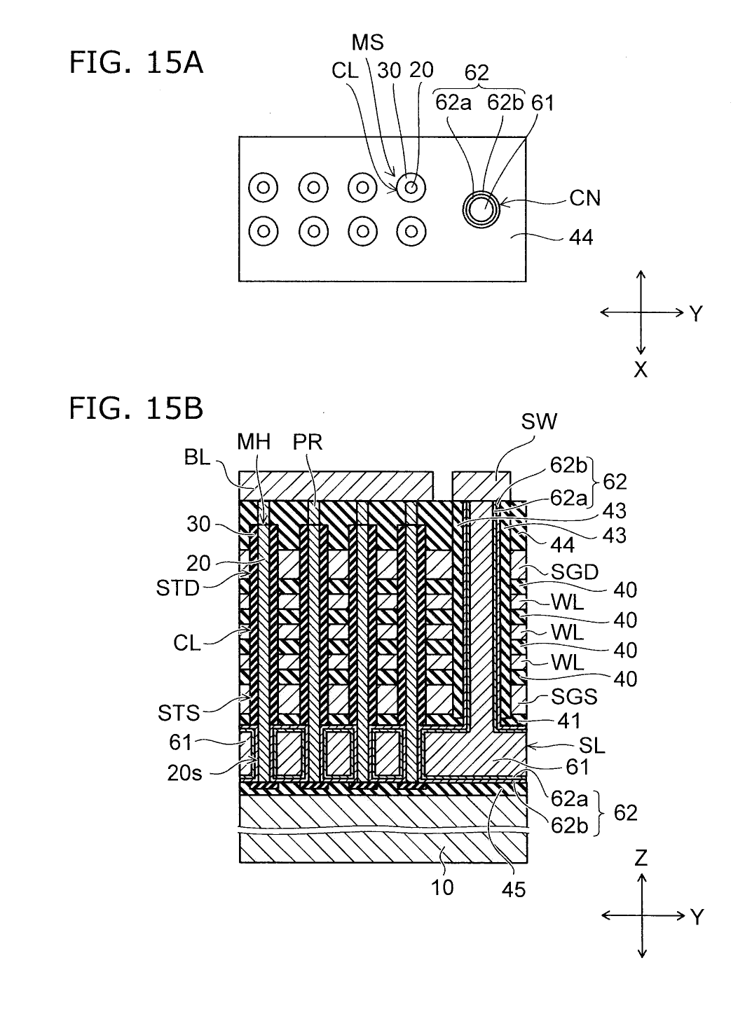

FIG. 15A is a schematic top view of the memory strings MS in another embodiment. FIG. 15B is a schematic sectional view of the memory strings MS in the other embodiment.

According to the embodiment, as shown in FIG. 15B, the channel bodies 20 pierce through the source layer SL. The channel bodies 20 include, in portions where the channel bodies 20 pierce through the source layer SL, side surfaces 20s not covered with the memory film 30.

The side surfaces 20s of the channel bodies 20 are in contact with the barrier film 62. The side surfaces 20s of the channel bodies 20 are covered with the barrier film 62 and covered with the source film 61 via the barrier film 62. That is, the channel bodies 20 are electrically connected to the source layer SL via the side surfaces 20s. The configuration of the source layer SL including the barrier film 62 and the source film 61 is the same as the configuration of the embodiment described above.

According to the embodiment, the side surfaces 20s of the channel bodies 20 in contact with the source layer SL are equivalent to the portions where the channel bodies 20 pierce through the source layer SL. Therefore, the area of the channel bodies 20 in contact with the source layer SL is larger than the area of the end faces (the bottom surfaces) of the channel bodies 20. Contact resistance is lower when the channel bodies 20 are in contact with the source layer SL on the side surfaces 20s and the bottom surfaces than when the channel bodies 20 are in contact with the source layer SL only on the bottom surfaces.

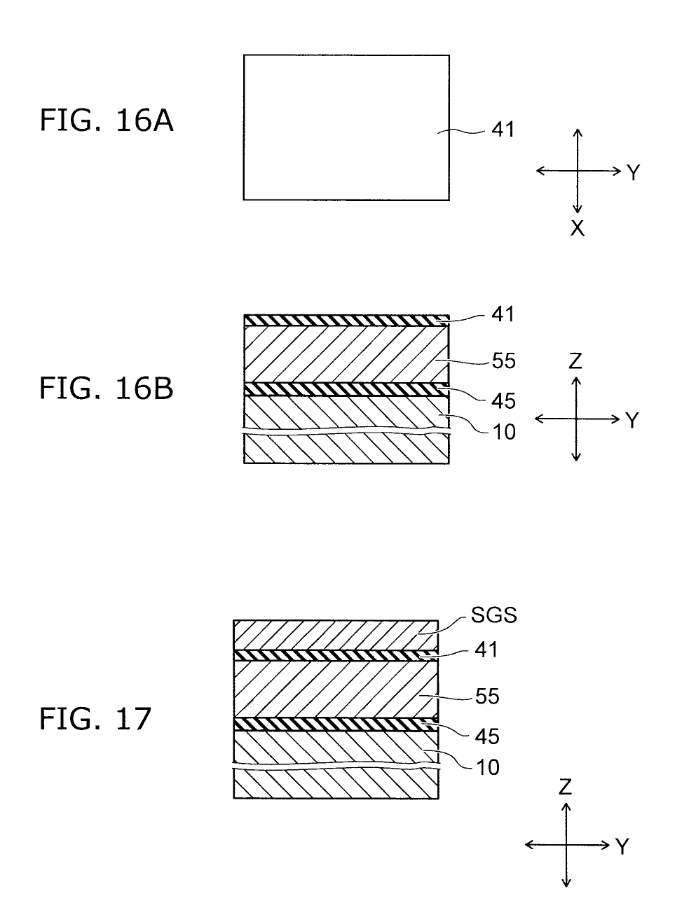

A method for manufacturing the semiconductor memory device in the other embodiment is described with reference to FIGS. 16A to 26B.

FIGS. 16B, 17 to 22, 23B, 24B, 25B, and 26B are schematic sectional views.

FIGS. 16A, 23A, 24A, 25A, and 26A are respectively schematic top views of processes shown in FIGS. 16B, 23B, 24B, 25B, and 26B.

As shown in FIG. 16B, as in FIG. 4B of the embodiment described above, the insulating layer 45 (the foundation layer), the sacrificial layer 55, and the insulating layer 41 are formed on the substrate 10.

As shown in FIG. 16A, in the embodiment, the separating sections 70 do not have to be formed.

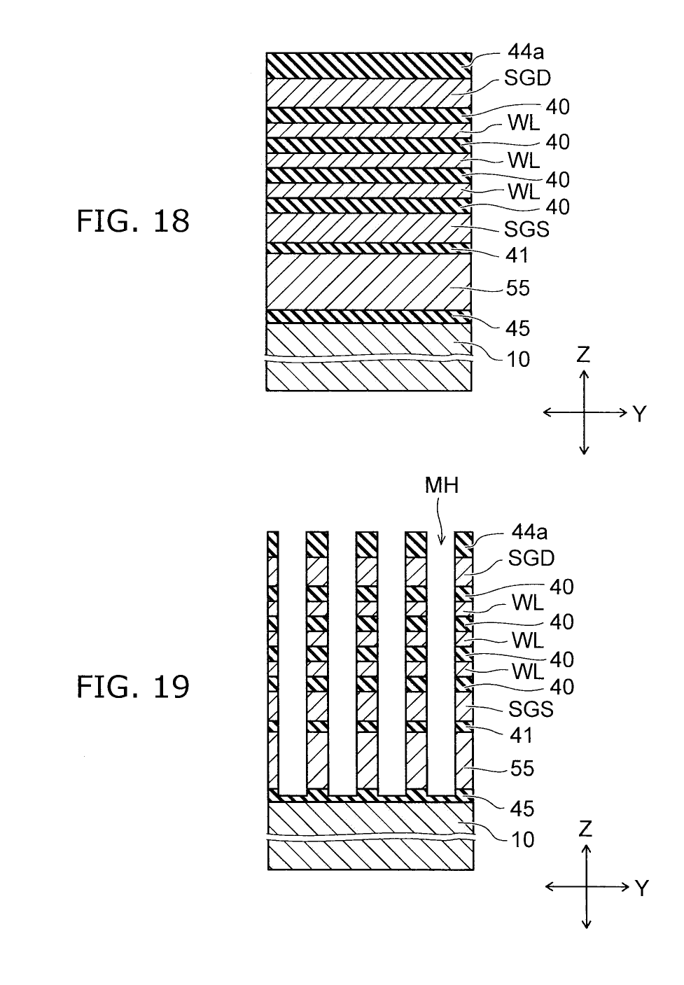

As shown in FIGS. 17 and 18, as in FIGS. 5 and 6 of the embodiment described above, the source side selection gate SGS, the stacked body in which the insulating layers 40 and the electrode layers WL are alternately stacked, the drain side selection gate SGD, and the insulating layer 44a are formed.

Subsequently, as shown in FIG. 19, the plurality of memory holes MH are formed in the stacked body. The memory holes MH are formed by, for example, the RIE method using a not-shown mask. The memory holes MH pierce through the insulating layer 44a to the sacrificial layer 55 and reach the insulting layer 45.

The insulating layer (the foundation layer) 45 functions as an etching stopper in the formation of the memory holes MH. Therefore, the insulating layer 45 is a layer made of a material different from the material of a silicon layer such as the electrode layer WL and a silicon oxide layer such as the insulating layer 40 and including, for example, tantalum oxide.

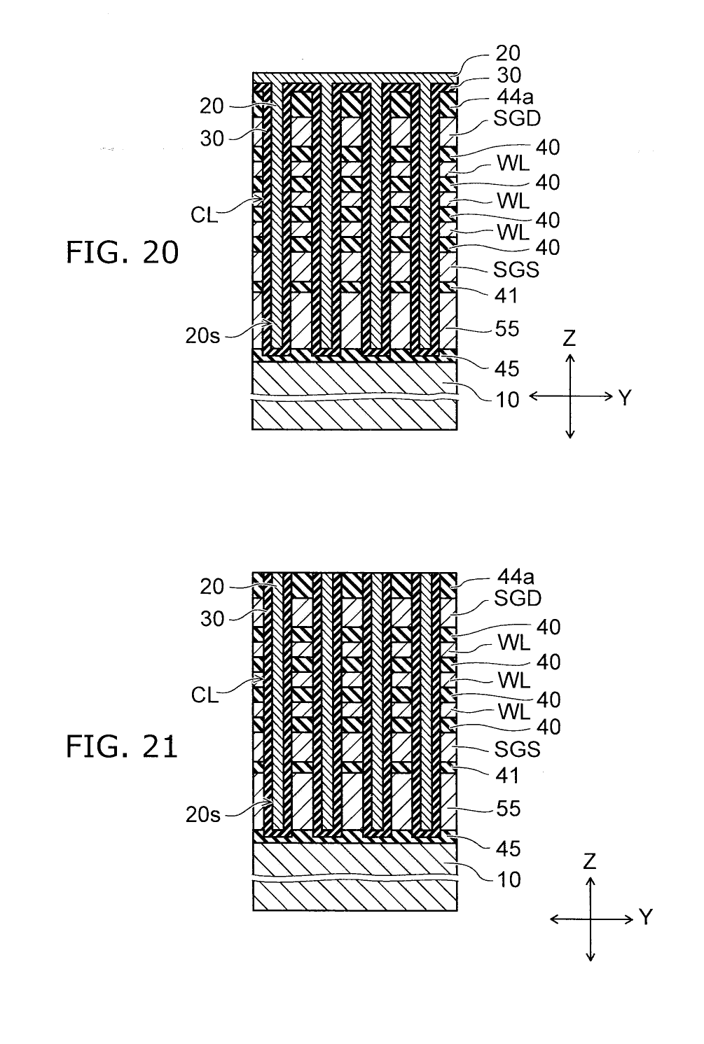

After the memory holes MH are formed, as shown in FIG. 20, the films (the films including the memory film 30 and the channel bodies 20) shown in FIG. 3 are formed in order on the inner walls (the sidewalls and the bottoms) of the memory holes MH. Consequently, the columnar sections CL are formed.

In this case, the side surfaces 20s of the portions where the channel bodies 20 pierce through the sacrificial layer 55 are covered with the memory film 30. The memory film 30 that covers the side surfaces 20s of the channel bodies 20 is covered with the sacrificial layer 55.

The films formed on the insulating layer 44a are removed as shown in FIG. 21.

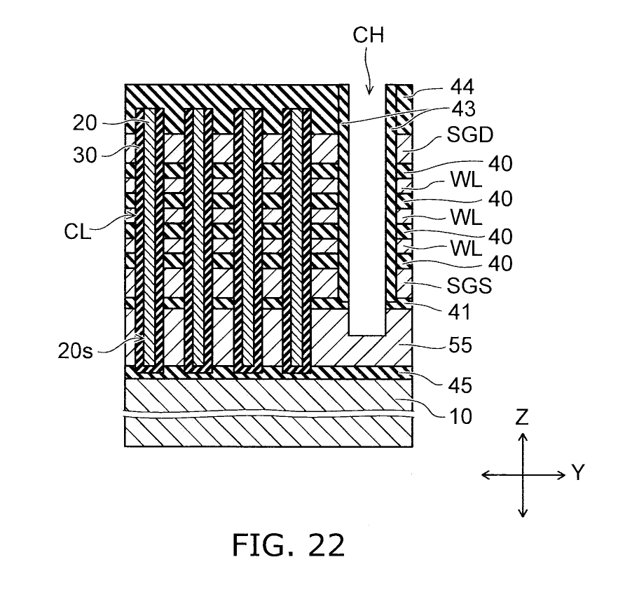

As shown in FIG. 22, the insulating layer 44 is formed on the columnar sections CL and the stacked body.

The contact hole CH that pierces through the insulating layer 44 to the insulating layer 41 and reaches the sacrificial layer 55 is formed in the stacked body. The sacrificial layer 55 is exposed in the bottom of the contact hole CH.

The insulating film 43 is formed on the sidewall of the contact hole CH. Therefore, the side surfaces of the electrode layers WL, the source side selection gate SGS, and the drain side selection gate SGD exposed on the sidewall of the contact hole CH are covered with the insulating film 43.

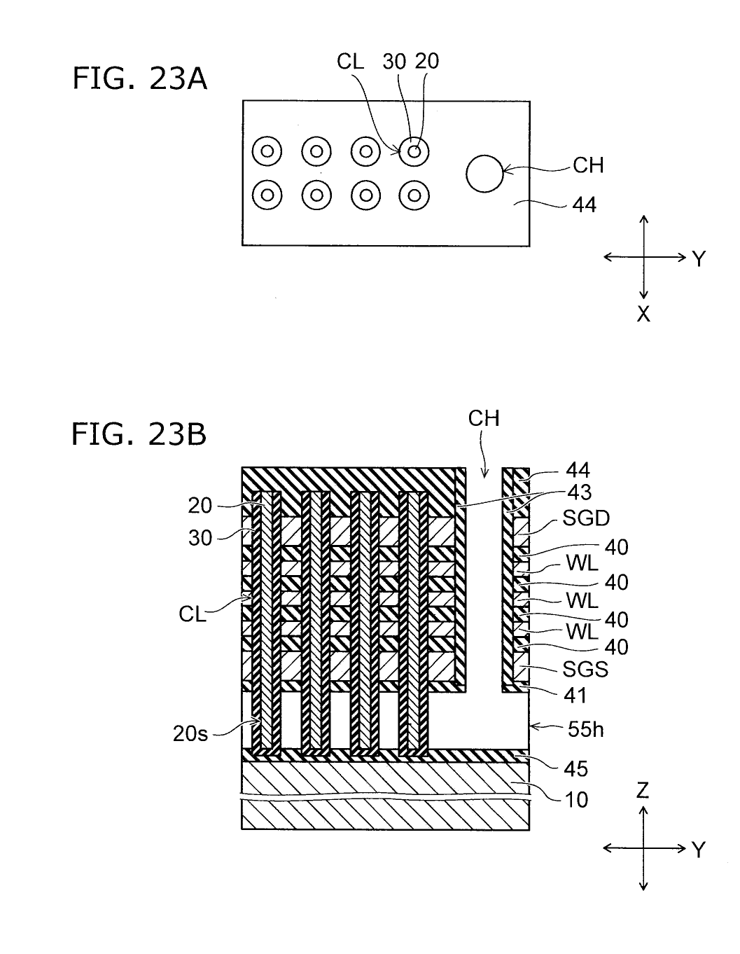

As shown in FIG. 23B, the sacrificial layer 55 is removed with etching performed through the contact hole CH. As a method for removing the sacrificial layer 55, for example, alkali chemical liquid is used. Consequently, the cavity 55h is formed under the stacked body. The cavity 55h is connected to the contact hole CH. The side surfaces 20s of the channel bodies 20 pierce through the cavity 55h and are covered with the memory film 30. The memory film 30 that covers the side surfaces of the channel bodies 20 is exposed in the cavity 55h.

In this case, the stacked body is supported by the columnar sections CL that pierce through the cavity 55h and reach the insulating layer 45.

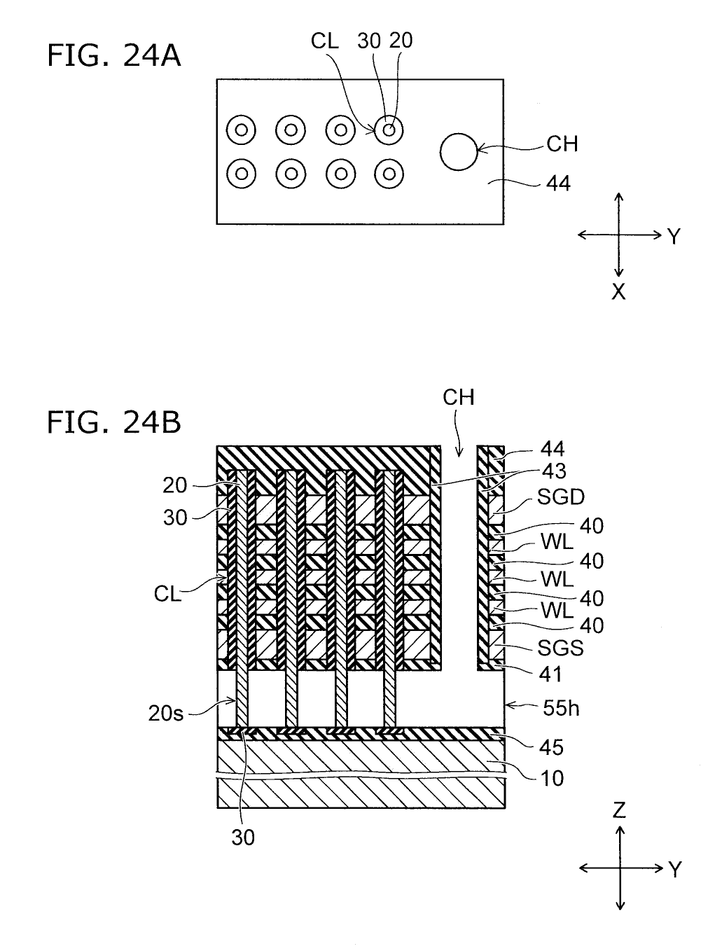

Thereafter, the memory film 30 exposed in the cavity 55h is removed with etching performed through the contact hole CH. For example, the memory film 30 is removed by CDE (Chemical Dry Etching). Consequently, as shown in FIG. 24B, the side surfaces 20s of the channel bodies 20 that pierce through the cavity 55h are exposed in the cavity 55h without being covered with the memory film 30.

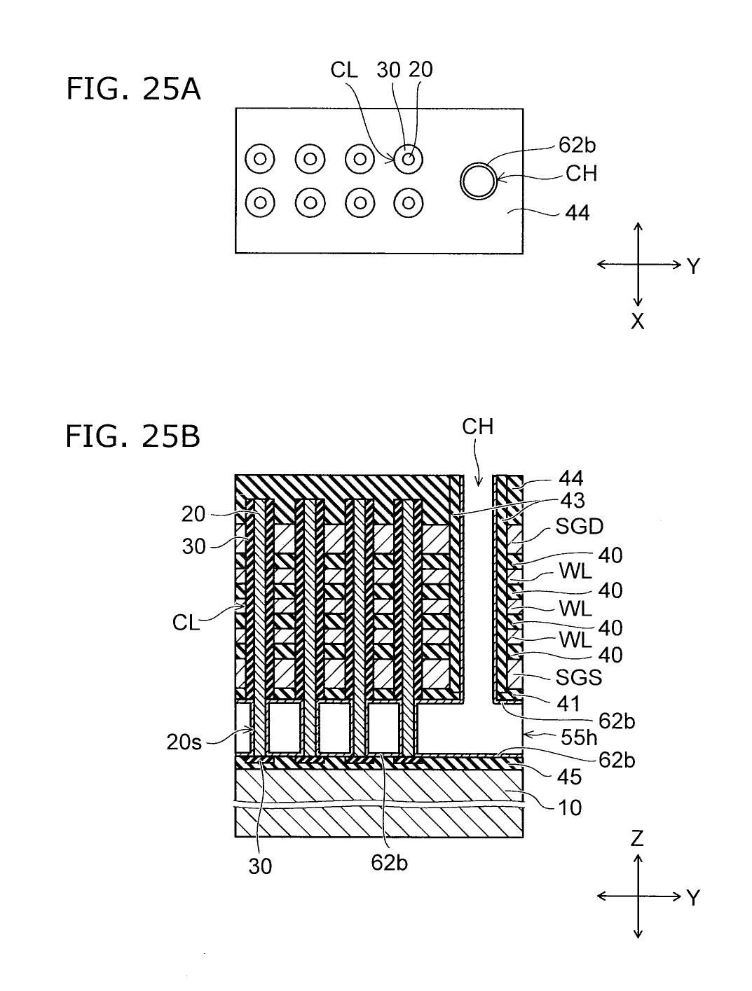

Thereafter, as shown in FIG. 25B, the conductive film 62b is formed on the inner wall of the cavity 55h and the sidewall of the contact hole CH. The conductive film 62b is integrally formed with the inner wall of the cavity 55h and the sidewall of the contact hole CH. That is, the same conductive film 62b is formed on the sidewall of the contact hole CH and the inner wall of the cavity 55h.

The side surfaces 20s of the channel bodies 20 exposed in the cavity 55h are covered with the conductive film 62b. The conductive film 62b is formed in a conformal manner along the side surfaces 20s of the channel bodies 20 and the inner wall of the cavity 55h.

The conductive film 62b is, for example, a silicon film doped with impurities.

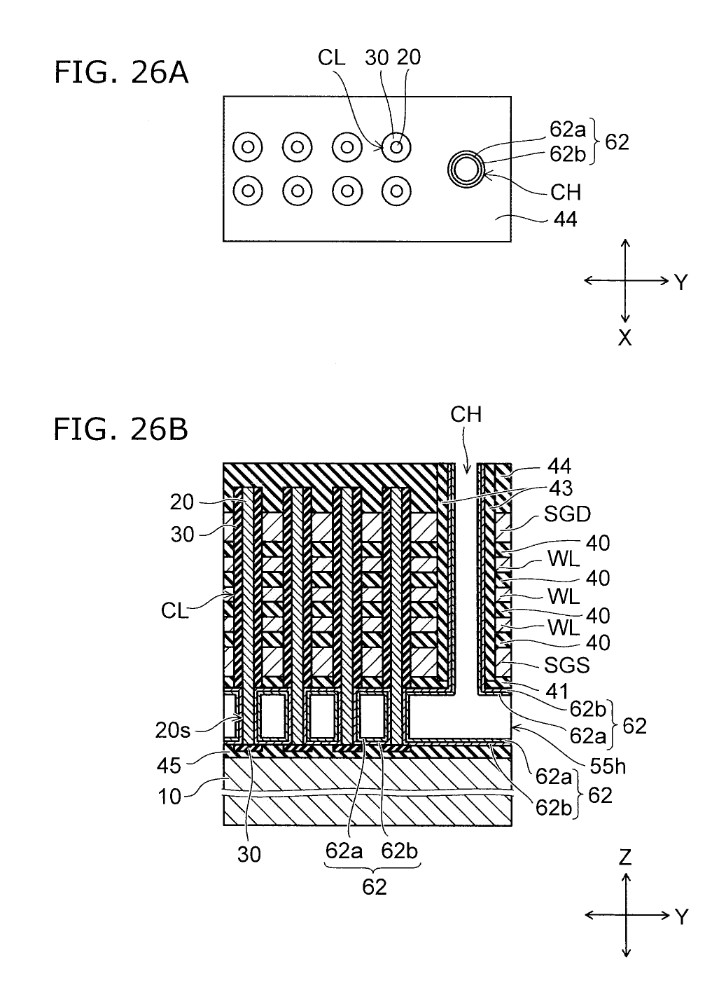

As shown in FIG. 26B, another conductive film 62a is formed on the conductive film 62b. The conductive film 62a covers the inner wall of the cavity 55h and the sidewall of the contact hole CH via the conductive film 62b. The conductive film 62a covers the side surfaces 20s of the channel bodies 20 in a conformal manner via the conductive film 62b.

Thereafter, the source film 61 is embedded in the cavity 55h and the contact hole CH. Consequently, the source layer SL and the contact section CN are formed as shown in FIG. 15B.

Thereafter, the bit lines BL and the like are formed on the insulating layer 44. Consequently, the semiconductor memory device of the embodiment is obtained.

In the embodiment, as in the embodiment described above, it is possible to etch only the memory film 30 formed under the stacked body including the electrode layers WL. Therefore, the memory film 30 of the memory cells formed above the source layer SL is not affected by the etching. Therefore, it is possible to suppress characteristic fluctuation and deterioration of the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a source layer;
a stacked body provided on the source layer and including a plurality of electrode layers and a plurality of insulating layers respectively provided among the electrode layers;
a columnar section extending in a stacking direction of the stacked body and piercing through the stacked body; and
a contact section extending in the stacking direction and piercing through the stacked body and connected to the source layer,
the columnar section including:
a channel body extending in the stacking direction and including a lower end, the lower end projecting into the source layer; and
a charge storage film provided between the channel body and each of the electrode layers, and
the source layer including:
a first film including metal; and
a second film having electric conductivity provided between the first film and the lower end of the channel body, the second film being in contact with the lower end and covering the lower end.

2. The device according to claim 1, wherein the contact section includes:
a third film integrally provided with the first film and made of a material same as a material of the first film; and
a fourth film provided between the third film and the stacked body and integrally provided with the second film and made of a material same as a material of the second film.

3. The device according to claim 2, wherein the second film and the fourth film include metal.

4. The device according to claim 1, wherein the second film includes:
a first conductive film provided between the first film and the lower end of the channel body and including silicon, the first conductive film being in contact with the lower end and covering the lower end; and
a second conductive film provided between the first film and the first conductive film and including metal.

5. The device according to claim 2, wherein
the second film includes:
a first conductive film provided between the first film and the lower end of the channel body and including silicon, the first conductive film being in contact with the lower end and covering the lower end; and
a second conductive film provided between the first film and the first conductive film and including metal, and
the fourth film includes:
a third conductive film integrally provided with the first conductive film and made of a material same as a material of the first conductive film; and
a fourth conductive film provided between the third film and the third conductive film and integrally provided with the second conductive film and made of a material same as a material of the second conductive film.

6. The device according to claim 1, further comprising a separating section that separates the source layer into a plurality of regions under the stacked body.

7. The device according to claim 1, wherein the second film is in contact with a bottom surface and a side surface of the lower end of the channel body.

8. The device according to claim 2, wherein the first film and the third film include tungsten.

9. The device according to claim 1, wherein the stacked body further includes:
a lower gate layer provided between the source layer and the electrode layer at a bottom; and
an upper gate layer provided on the electrode layer at a top.

10. A semiconductor memory device comprising:
a foundation layer;
a source layer provided on the foundation layer;
a stacked body provided on the source layer and including a plurality of electrode layers and a plurality of insulating layers respectively provided among the electrode layers;
a columnar section extending in a stacking direction of the stacked body and piercing through the stacked body and the source layer and reaching the foundation layer; and
a contact section extending in the stacking direction of the stacked body and piercing through the stacked body and connected to the source layer,
the columnar section including:
a channel body extending in the stacking direction and including a side surface, the side surface connected to the source layer under the stacked body; and
a charge storage film provided between the channel body and each of the electrode layers, and
the source layer including:
a first film having electric conductivity; and
a second film having electric conductivity provided between the first film and the side surface of the channel body, the second film being in contact with the side surface and covering the side surface.

11. The device according to claim 10, wherein the contact section includes:
a third film integrally provided with the first film and made of a material same as a material of the first film; and
a fourth film provided between the third film and the stacked body and integrally provided with the second film and made of a material same as a material of the second film.

12. The device according to claim 11, wherein the first film and the third film include metal.

13. The device according to claim 11, wherein the second film and the fourth film include metal.

14. The device according to claim 10, wherein the second film includes:
a first conductive film provided between the first film and the side surface of the channel body and including silicon, the first conductive film being in contact with the side surface and covering the side surface; and
a second conductive film provided between the first film and the first conductive film and including metal.

15. The device according to claim 10, wherein
the second film includes:
a first conductive film provided between the first film and the side surface of the channel body and including silicon, the first conductive film being in contact with the side surface and covering the side surface; and
a second conductive film provided between the first film and the first conductive film and including metal, and
the fourth film includes:
a third conductive film integrally provided with the first conductive film and made of a material same as a material of a first conductive film; and
a fourth conductive film provided between the third film and the third conductive film and integrally provided with the second conductive film and made of a material same as a material of the second conductive film.

16. The device according to claim 11, wherein the first film and the third film include tungsten.

17. The device according to claim 10, wherein the foundation layer includes tantalum oxide.

18. The device according to claim 10, wherein the stacked body includes:
a lower gate layer provided between the source layer and the electrode layer at a bottom; and
an upper gate layer provided on the electrode layer at a top.

19. A method for manufacturing a semiconductor memory device comprising:
forming, on a sacrificial layer, a stacked body including a plurality of electrode layers and a plurality of insulating layers respectively provided among the electrode layers;
forming a hole that reaches the sacrificial layer piercing through the stacked body;
forming a film including a charge storage film on a sidewall of the hole;
forming a channel body on a sidewall of the film including the charge storage film;
forming a hole or a groove-like pierce-through section that reaches the sacrificial layer piercing through the stacked body;
removing the sacrificial layer with etching performed through the pierce-through section and forming a cavity under the stacked body;
removing a film including the charge storage film exposed in the cavity with the etching performed through the pierce-through section and exposing a part of the channel body in the cavity; and
forming a source layer in the cavity and connecting the part of the channel body to the source layer.

20. The method according to claim 19, wherein the hole pierces through the sacrificial layer.
